(19) United States
(12) Patent Application Publication
(10) Pub. No.: US 2026/0257449 A1
(43) Pub. Date: Sep. 3, 2026

(54) PRESSURE BALANCING MEMBRANE

(71) Applicant: GERGONNE SAS, Oyonnax (FR)

(72) Inventors: Charles GERGONNE, Arbent (FR); Bertrand GERGONNE, Arbent (FR)

(73) Assignee: GERGONNE SAS, Oyonnax (FR)

(21) Appl. No.: 19/164,119

(22) PCT Filed: Mar. 14, 2024
(86) PCT No.: PCT/FR2024/050308

§ 371 Date: Sep. 10, 2025

(30) Foreign Application Priority Data
Mar. 16, 2023 (FR) FR23/02438

(51) Int. Cl. B32B 3/08; B32B 5/02; B32B 27/12; B32B 27/32; B60R 16/023; F21V 29/83; H05K 5/02

(52) U.S. Cl. CPC B32B 3/08; B32B 5/022; B32B 27/12; B32B 27/322; B60R 16/0239; B32B 2305/026; F21V 29/83; H05K 5/0214

(57) ABSTRACT

A pressure balancing membrane including a membrane wherein the membrane is sandwiched with a reinforcing edge.

The present invention relates to a pressure balancing membrane attended to be attached to the surface of an article (for example an enclosure containing electronic components) at a pressure balancing opening.

Many engineering devices (for example in the fields of vehicles, construction and housing) include enclosures, usually equipped with seals, which contain electronic components, and therefore must be perfectly sealed so as not to damage the electronic components to extend the service life of said devices. As examples, there can be mentioned the enclosures of earthmoving equipment, road construction equipment, cranes, forklifts, tractors or any other vehicle used in agriculture. It may also be a sealed enclosure of a car headlight or a spotlights for external use (for example to illuminate a garden or a monument).

It is well known to provide in these enclosures one or several openings, so-called “pressure balancing openings”.

Indeed, temperature variations during the day, seasons or during a change in altitude or even due to the production of heat by the device itself during its operation can cause pressure differences within a sealed enclosure. A sudden drop in temperature can create a vacuum inside the enclosure. If this pressure difference is not dissipated, the vacuum exerts continuous tension on the seals of the enclosure which ensure its sealing. Over time, this can cause the seals to wear, allowing moisture and other contaminants (for example dust, dirt) to enter the enclosure which will damage and/or oxidize the electronic components.

These pressure balancing openings are therefore necessary to allow the air present within the enclosure to expand, to be evacuated (in case of increase in temperature) or to flow in (in case of cooling).

As example, the electronic components of an automobile, designed in particular to control the parameters of the automobile, produce heat during operation which generates self-heating of said electronic components but also heating of the air present within the enclosure. Without pressure balancing thanks to these pressure balancing openings, an excess of pressure could occur within the enclosure, reaching 300, 500 or 700 mbar depending on the ambient temperature and the intensity of use of the electronic components (in other words their electrical energy consumption).

Additionally, the presence of moisture within a sealed enclosure can be very damaging to the device. Indeed, when water vapor enters a sealed enclosure and has no way to escape, it condenses and becomes liquid. If this condensation remains inside the sealed enclosure, it risks compromising the proper operation of the electronic components, in particular by oxidizing them.

Finally, the pressure balancing openings must not be exposed to dirt (dust, particles carried by the wind), rain, external elements (par example insects, gravel, sand) so as not to damage the electronic components present inside the sealed enclosures.

Therefore, for all these reasons, it is known to cover these openings with pressure balancing membranes.

These pressure balancing membranes are therefore designed to:
allow gas exchanges so as to balance the pressures within the enclosure (depending on the different climatic events or operating conditions of the elements of the enclosure or more generally of the device in which the enclosure is integrated) and to reduce condensation within the enclosure which can oxidize sensitive electronic components,
prevent the entry into the enclosure of dirt (for example particles carried by the wind or dust), water, humidity, mold, external elements (insects, gravel, sand) so as not to damage the electronic components so that they operate reliably and durably, whatever the conditions of use of the device comprising said enclosure.

Additionally, in the case where the enclosure contains a battery, its charging cycles can generate heat and emit hydrogen or other gases. This can cause explosions. The pressure balancing membranes effectively dissipate these gases. Thus, by continuously balancing pressures within the enclosure, such membranes reduce the risk of explosion.

In other words, these pressure balancing membranes are designed to protect the electronic components in the harshest environments and conditions. They combine permeability to gases (especially air) with protection of the electronic components against the various external elements and contaminants mentioned above (dirt, dust, water, humidity, insects, sand, gravel, etc.).

More specifically, with regard to gas permeability, these membranes provide a compact ventilation structure, easily installed and integrated on the device (for example on an enclosure including electronic components).

The pressure balancing membranes are designed to quickly balance pressure variations within sealed enclosures effectively preventing the aforementioned internal voids or the pressure build-ups that:
pressurize the seals of the sealed enclosures and prematurely damage them,
attract the aforementioned external contaminants inside the sealed enclosures.

These pressure balancing membranes must therefore be mechanically robust enough to be able to withstand bad weather, the aforementioned external contaminants (in particular gravel), as well as the pressure fluctuations mentioned above.

Reliable and durable pressure balancing membranes extend the service life of the device, reducing thus its maintenance costs.

To ensure all these functions listed above, the pressure balancing membranes are generally made of a microporous film of polymeric material, preferably polytetrafluoroethylene, hereinafter abbreviated as “PTFE”. This film of polymeric material is sufficiently microporous to allow gas exchanges (particularly air) through the membrane while presenting a certain sealing and robustness to prevent liquids or other aforementioned contaminants (dirt, sand, gravel, insects) from passing through said membrane. The thickness of such membranes made of PTFE is in the range of 300 μm.

However, PTFE has the disadvantages of being an expensive material, non-recyclable, requiring toxic and hazardous materials for its production and producing greenhouse gases or toxic products when heated. Therefore, in order to limit the costs and environmental impact of the pressure balancing membrane without reducing its robustness and its gas permeability and liquid sealing functions, it is known to limit the quantity of PTFE by providing a double-layer membrane which has:
a 1st layer of PTFE film with reduced thickness compared to single-layer PTFE membranes, namely from 20 μm to 30 μm,
a 2nd layer of a textile material (with a thickness of approximately 100 μm) which has, for example, been attached to the 1st layer of PTFE film with a plurality of glue dots with a thickness of approximately 10 μm.

In this embodiment, it is known to a person skilled in the art that the pressure balancing membrane must be attached to the pressure balancing opening emerging into a sealed space of a device in such a way that:
the 2nd layer of textile material faces the sealed space and
the 1st layer of PTFE film faces the outside of this sealed space.

In this way, the textile material is not at risk of being delaminated or torn off from the layer of PTFE film when the pressure balancing membrane is subjected to drastic external conditions (for example climatic: heavy rain) or comes into contact with external elements (for example gravel).

However, this embodiment is not entirely satisfactory, because the 1st layer of PTFE film is thinner, so it can be more easily damaged than a single-layer membrane of PTFE film. For example, in the case of an enclosure of a car headlight, the membrane can be more easily abraded, scratched or subjected to an impact. This will reduce its sealing, and consequently that of the enclosure, and have an impact on the service life of the device.

Finally, the pressure balancing membranes are generally provided over the entire periphery of the face intended to be opposite the confined space of the device with a layer of a means for attaching to the device. This attachment means is generally in the form of a frame whose external edge corresponds to the periphery of the membrane and which includes a face covered with an adhesive to be able to attach the membrane at the pressure balancing opening. Thus, a significant part of the surface of the membrane (namely over its entire periphery) is covered by the attachment means and therefore does not contribute to the aforementioned gas exchanges. In other words, a significant part of the pressure balancing membrane is “sacrificed” to allow its attachment to the device.

US patent application 2014/0283691 A1 describes a sealed ventilation structure that comprises an enclosure having an opening and an air-permeable, sealed membrane that covers the opening. A space inside and a space outside the enclosure communicate with each other through the opening covered by the membrane. The membrane comprises two layers of materials. Double-sided adhesives serve as a means for attaching the membrane on one hand to the enclosure and on the other hand to the electronic component to be protected, which the enclosure contains. These double-sided adhesives are located flush with the membrane. None of these adhesives protrude beyond the periphery of the membrane.

The U.S. Pat. No. 9,875,733 B2 describes a ventilation device which comprises a membrane which is divided into a central part and a peripheral part surrounding said central part. The peripheral part is bonded:
at a 1st face of the membrane to a layer of foam laminate having an adhesive face;

and
at a 2nd face of the membrane to a double-adhesive polyester film.

The laminate layer and the double-adhesive polyester film sandwich the membrane flush around its entire periphery.

In summary, the pressure balancing membranes known to date have various disadvantages (depending on their different embodiments detailed above) which are in particular the expensive and non-ecological nature of PTFE, the lack of robustness in the face of bad weather or external elements (gravel) with the risk of tearing or loss of sealing.

The inventors of the present invention sought to overcome these drawbacks and developed a pressure balancing membrane having the following advantages:
said membrane can include a reduced quantity of PTFE allowing to reduce its economic and environmental impact;
an excellent durability;
an excellent resistance to drastic climatic conditions and operating conditions of the device in which said membrane is incorporated, as well as to the aforementioned external elements (gravel, dust, etc.).

The present invention thus relates to a pressure balancing membrane including a membrane and a reinforcing edge, part or all of the periphery of said membrane is sandwiched with said reinforcing edge which includes a 1st element and a 2nd element,
the 1st element and the 2nd element each comprise a support layer,
the support layer of the 1st element has a 1st face and a 2nd face,
the support layer of the 2nd element has a 1st face and a 2nd face,
said pressure balancing membrane is characterized in that:
   a part of the 2nd face of the support layer of the 2nd element is attached to a part of the 1st face of the support layer of the 1st element, the remaining part of the 2nd face of the support layer of the 2nd element is attached to a part of the membrane, as well as the remaining part of the 1st face of the support layer of the 1st element is attached to a part of the membrane
or
   the entire 2nd face of the support layer of the 2nd element is attached to the membrane and a part of the 1st face of the support layer of the 1st element is attached to the membrane.

The 1st face of the support layer of the 2nd element of the reinforcing edge is intended to be attached to a device provided with a confined space emerging onto a pressure balancing opening so that the pressure balancing membrane according to the invention covers said opening of the device.

The 2nd face of the support layer of the 1st element of the reinforcing edge is intended to be in contact with the environment external to the confined space emerging onto the pressure balancing opening which is covered by the pressure balancing membrane according to the invention.

In the embodiment of the invention in which the entire 2nd face of the support layer of the 2nd element is attached to the membrane and a part of the 1st face of the support layer of the 1st element is attached to the membrane, the remaining part of the 1st face of the support layer of the 1st element of the reinforcing edge will be intended to be attached to a device, more precisely around the periphery of a pressure balancing opening with which said device is provided.

Preferably, the entire periphery of the membrane is sandwiched with the reinforcing edge.

In one embodiment of the invention, a part of the periphery of the membrane is sandwiched with the reinforcing edge. Preferably, more than 20%, more preferably more than 50%, of the periphery of the membrane is sandwiched with the reinforcing edge.

In the context of the present invention, the terms “part or all of the periphery of the membrane is sandwiched with the reinforcing edge which includes a 1st element and a 2nd element” means that said membrane is located between said 1st element and the 2nd element. According to embodiments of the invention, the 1st element and the 2nd element may both protrude from the periphery of the membrane or, according to other embodiments of the invention, only the 1st element may protrude from the periphery of the membrane and the 2nd element will be located flush with the periphery of the membrane. All these embodiments of the invention have in common that the membrane is always located between the 1st element and the 2nd element, therefore well sandwiched by the reinforcing edge.

Sandwiching the membrane with a reinforcing edge has the following advantages: not only does the reinforcing edge reinforces the membrane and therefore make it more resistant to drastic climatic conditions or external aggressions (for example gravel) which are likely to damage it and/or tear it off, but it also makes it possible to reduce the necessary quantity of the membrane. Indeed, due to the sandwiching of the membrane with the reinforcing edge, it is no longer necessary for a significant part of the membrane to be “sacrificed” to allow its attachment to the device. Indeed, a part of the reinforcing edge contributes to the attachment of the pressure balancing membrane according to the invention to the device.

The pressure balancing membrane according to the invention includes a membrane, for example a membrane as known from the condition of the art and examples of which have been detailed above.

The membrane can thus present the following technical characteristics which are not limiting.

The membrane can have any geometric shape. For example, the membrane can be square, rectangular, oval, round, triangular or any other polygonal shape.

The surface of the membrane can be comprised between 0.1 cm² and 100 cm², preferably between 1 cm² and 30 cm².

The thickness of the membrane can be comprised between 20 μm and 2 mm.

The membrane may comprise at least one microporous material which has breathability, measured by an air flow rate passing through the membrane under pressure of +70 mbar, between 10 and 10000 mL/min/cm².

The membrane can be single-layer or multi-layer. If it is multi-layer, it is preferably double-layer.

In embodiments of the invention, the membrane comprises at least one microporous film of polymeric material. It may be a polymeric material selected from polymers having a low surface energy, preferably less than 40 mN/cm. The polymeric material may be selected from PTFE, polychlorotrifluoroethylene (hereinafter abbreviated as “PCTFE”), polyvinyl fluoride (hereinafter abbreviated as “PVF”), polysiloxane, polycarbonate (hereinafter abbreviated as “PC”) and polyester. The microporous film of polymeric material preferably has pores with a size comprised between approximately 0.01 μm and approximately 50 μm. Most preferably, the polymeric material of the membrane is PTFE.

In the context of the present invention, in order to allow the aforementioned gas exchanges through the membrane, the film of polymeric material is microporous.

In embodiments of the invention, the membrane is single-layer and includes a microporous film of polymeric material, preferably of a polymeric material as described above. In other words, the membrane is a single-layer microporous film of polymeric material which is selected from PTFE, PCTFE, PVF, polysiloxane, PC and polyester. In these embodiments of the invention, the thickness of said membrane may be comprised between 20 μm and 2 mm.

Examples of such single-layer membranes are in particular the membrane marketed by the company MICROVENT under the trade name MV72040, the membrane marketed by the company GORE under the trade name AVS 9 and the membrane marketed by the company BERGHOF under the trade name M40W.

In other embodiments of the invention, the membrane is double-layer and comprises a 1st layer of microporous film of polymeric material, for example of a polymeric material as described above and a 2nd layer of textile material which is attached to said 1st layer of microporous film of polymeric material.

The textile material may be selected from textiles based on polyethylene terephthalate (hereinafter abbreviated as “PET”), polyamides, polypropylene, polyethylene, acrylic, PTFE, elastane, glass fibers, carbon or cellulose. Preferably, these are textiles based on PET or polyamides. The textile material may be obtained by a weaving method or by agglomeration of fibers or yarns such as nonwovens and felts.

Thus, in one embodiment of the invention, the membrane is double-layer and comprises a 1st layer of microporous film of polymeric material selected from PTFE, PCTFE, PVF, polysiloxane, PC and polyester and a 2nd layer of textile material which is attached to said 1st layer of microporous film of polymeric material, said textile material being selected from textiles based on PET, polyamides, polypropylene, polyethylene, acrylic, PTFE, elastane, glass fibers, carbon or cellulose.

In this embodiment of the invention, the thickness of the 1st layer of microporous film of polymeric material can be comprised between 10 μm and 500 μm and the thickness of the 2nd layer of textile material can be comprised between 10 μm and 1990 μm.

The 2nd layer of textile material can be attached to the 1st layer of microporous film of polymeric material with a glue suitable for adhesion between the textile material and the polymeric material (for example: a cyanoacrylate-based glue or a hot-melt or heat-reactivatable glue) or with another attachment means consisting of heat-sealing the textile material with the polymeric material. The attachment of the 2nd layer of textile material is advantageously performed to a part of the 1st layer of microporous film of polymeric material so as to always allow the aforementioned gas exchanges through the membrane. In other words, the means for attaching the textile material and the film of polymeric material is selected appropriately so as not to hinder gas exchanges through the membrane. This choice is perfectly within the reach of a person skilled in the art.

These embodiments of the invention in which the membrane is double-layer have the advantages of reducing the cost and environmental impact of the pressure balancing membrane. Indeed, the membrane includes a reduced quantity of microporous film of polymeric material (preferably PTFE) which is generally expensive and the synthesis method of which has an impact on the environment.

Examples of such double-layer membranes are in particular the membrane marketed by the company PARKER under the trade name QBV657D, the membrane marketed by the company BERGHOF under the trade name M100WL and the membranes marketed by the company DONALDSON under the trade names EN0711066 and EN0701435.

In other conceivable embodiments of the invention, the membrane comprises more than 2 layers of materials. For example, it may be an alternation of layers of films of polymeric materials and textile materials.

The 1st and 2nd elements of the reinforcing edge can each have the shape of a frame whose opening has a shape similar to the periphery of the membrane.

In one embodiment of the invention, the external dimensions of the frame of the 1st element and of the 2nd element of the reinforcing edge may be identical.

In another embodiment of the invention, the external dimensions of the frame of the 1st element of the reinforcing edge may be greater than the external dimensions of the frame of the 2nd element of the reinforcing edge. In this embodiment, a part of the face of the 1st element which is opposite that intended to be in contact with the external environment will be intended to be attached to a device on the periphery of a pressure balancing opening with which it is provided.

The thickness of the 1st element of the reinforcing edge can be comprised between 20 μm and 500 μm.

The thickness of the 2nd element of the reinforcing edge can be comprised between 30 μm and 500 μm.

In one embodiment of the invention:
the 1st element of the reinforcing edge can cover between 5% and 60% of the surface of the membrane,
the 2nd element of the reinforcing edge can cover between 5% and 70% of the surface of the membrane,
the 2nd element of the reinforcing edge can cover between 0% and 90% of the surface of the 1st element of the reinforcing edge.

As explained above, the 2nd element of the reinforcing edge may be flush with the periphery of the membrane. In this case, there is no coverage of the 2nd element with the 1st element of the reinforcing edge, in other words 0% coverage of the 2nd element with the 1st element.

The percentage of coverage of the membrane by the 1st element of the reinforcing edge is selected appropriately to reinforce the pressure balancing membrane according to the invention so that it is not torn off and/or damaged when it is subjected to drastic climatic conditions and/or in contact with external elements (for example gravel).

The percentage of coverage of the membrane by the 2nd element of the reinforcing edge is selected appropriately to allow a good attachment of the pressure balancing membrane according to the invention at the pressure balancing opening of the device. Moreover, in the embodiment of the invention in which the external dimensions of the frame of the 1st element of the reinforcing edge are greater than the external dimensions of the frame of the 2nd element of the reinforcing edge, the 1st element also contributes to the attachment of the pressure balancing membrane according to the invention at the pressure balancing opening of the device.

The percentage of coverage of the 1st element of the reinforcing edge by the 2nd element of the reinforcing edge is selected appropriately to ensure a good reinforcement of the membrane which is sandwiched between the 1st element and the 2nd element of the reinforcing edge. Indeed, the assembly constituted by the part of the 1st element of the reinforcing edge and by the part of the 2nd element of the reinforcing edge which are in contact with each other constitutes an excellent reinforcement of the pressure balancing membrane according to the invention.

Advantageously, the percentage of coverage of the membrane by the 2nd element of the reinforcing edge is greater than the percentage of coverage of the membrane by the 1st element of the reinforcing edge. This allows an excellent attachment of the pressure balancing membrane according to the invention on the periphery of a pressure balancing opening of a device through the 2nd element of the reinforcing edge.

Over all or part of the periphery of the membrane, between 0.5 mm and 20 mm, preferably between 1 mm and 10 mm, more preferably between 1 mm and 5 mm, of the membrane may be covered by the 1st element of the reinforcing edge. This means that when the membrane is for example rectangular in shape, over all or part of the width of the membrane and over all or part of the length of the membrane, between 0.5 mm and 20 mm of the membrane are covered by the 1st element of the reinforcing edge.

Between 0.5 mm and 20 mm, preferably between 1 mm and 10 mm, more preferably between 1 mm and 5 mm, of the 1st element of the reinforcing edge may protrude over all or part of the periphery of the membrane. This means that when the membrane is for example rectangular in shape, between 0.5 mm and 20 mm of the 1st element of the reinforcing edge may protrude over all or part of the width of the membrane and over all or part of the length of the membrane.

Over all or part of the periphery of the membrane, between 0.5 mm and 20 mm, preferably between 1 mm and 10 mm, more preferably between 1 mm and 5 mm, of the membrane can be covered by the 2nd element of the reinforcing edge.

Between 0.5 mm and 20 mm, preferably between 1 mm and 10 mm, more preferably between 1 mm and 5 mm, of the 2nd element of the reinforcing edge may protrude over all or part of the periphery of the membrane.

The material of the support layer of the 1st element and of the 2nd element of the reinforcing edge can be selected from PET, poly(ethylene naphthalate) (abbreviated as “PEN”), polyvinyl chloride (abbreviated as “PVC”), polyamide, polypropylene and metal foil. The material of the support layer of the 1st element can be the same as or different from the material of the support layer of the 2nd element.

The thickness of the support layer of the 1st element of the reinforcing edge can be comprised between 15 μm and 200 μm, preferably between 30 μm and 100 μm.

The thickness of the support layer of the 2nd element of the reinforcing edge can be comprised between 15 μm and 200 μm, preferably between 30 μm and 100 μm.

The support layer of the 1st element can have a Young's modulus (measured according to ISO 527 standard) comprised between 0.5 GPa and 200 GPa, preferably between 1 GPa and 100 GPa, for example 5 GPa.

The support layer of the 2nd element may have a Young's modulus (measured according to ISO 527 standard) comprised between 0.5 GPa and 200 GPa, preferably between 1 GPa and 100 GPa, for example 5 GPa.

The support layer of the 1st element may have an elasticity, namely the force to obtain 5% elongation (measured according to ISO 527 standard), greater than 10 MPa, preferably greater than 50 MPa, for example 110 MPa.

The support layer of the 2nd element may have an elasticity, namely the force to obtain 5% elongation (measured according to ISO 527 standard), greater than 10 MPa, preferably greater than 50 MPa, for example 110 MPa.

The physical properties of the support layers of the 1st element and of the 2nd element are selected appropriately so that the reinforcing edge reinforces the membrane as explained above.

In embodiments of the invention, the 1st face of the support layer of the 1st element of the reinforcing edge and the 2nd face of the support layer of the 2nd element of the reinforcing edge may be covered with an adhesive.

A part of the 2nd face of the support layer of the 2nd element of the reinforcing edge can be glued to a part of the 1st face of the support layer of the 1st element of the reinforcing edge and the remaining part of the 2nd face of the support layer of the 2nd element of the reinforcing edge can be glued to a part of the membrane, as well as the remaining part of the 1st face of the support layer of the 1st element of the reinforcing edge can be glued to a part of the membrane.

Or the entire 2nd face of the support layer of the 2nd element of the reinforcing edge can be glued to the membrane and a part of the 1st face of the support layer of the 1st element of the reinforcing edge can be glued to the membrane. The remaining part of the 1st face of the support layer of the 1st element of the reinforcing edge will be intended to be attached to a device on the periphery of a pressure balancing opening with which it is provided.

The adhesive may advantageously be selected from pressure-sensitive adhesives, for example the adhesives based on acrylics, silicone, rubber or polyurethane.

The adhesive can optionally be tinted, for example with the incorporation of pigments or dyes so that the 1st element and the 2nd element of the reinforcing edge have the same color or a color similar to the color of the membrane.

The thickness of the adhesive may be comprised between 5 μm and 500 μm, preferably between 25 μm and 100 μm.

The 1st face of the support layer of the 2nd element of the reinforcing edge can also be covered with an adhesive. This allows the pressure balancing membrane according to the invention to be attached to a device in such a way that it covers a pressure balancing opening of the device. The 1st face of the support layer of the 2nd element of the reinforcing edge is attached to the device around the periphery of the pressure balancing opening.

The adhesive may advantageously be selected from pressure-sensitive adhesives, for example the adhesives based on acrylics, silicone, rubber or polyurethane.

The thickness of the adhesive may be comprised between 5 μm and 500 μm, preferably between 25 μm and 100 μm.

In other embodiments of the invention, the 1st face of the support layer of said 2nd element is devoid of adhesive. In these embodiments, an adhesive may be present around the periphery of a pressure balancing opening of a device so as to attach the 1st face of the support layer of the 2nd element of the reinforcing edge, on this adhesive. The adhesive may advantageously be selected from pressure-sensitive adhesives, for example the adhesives based on acrylics, silicone, rubber or polyurethane.

In other embodiments of the invention, the entire 1st face of the support layer of the 2nd element of the reinforcing edge can be attached by thermal welding to the periphery of said pressure balancing opening.

In one embodiment of the invention, a part of the 2nd face of the support layer of the 2nd element of the reinforcing edge is attached by thermal welding to a part of the 1st face of the support layer of the 1st element of the reinforcing edge. In addition, the remaining part of the 2nd face of the support layer of the 2nd element is attached by thermal welding to a part of the membrane and the remaining part of the 1st face of the support layer of the 1st element is attached by thermal welding to a part of the membrane.

In another embodiment of the invention, the entire 2nd face of the support layer of the 2nd element of the reinforcing edge is attached by thermal welding to the membrane and a part of the 1st face of the support layer of the 1st element of the reinforcing edge is attached by thermal welding to the membrane. The remaining part of the 1st face of the support layer of the 1st element of the reinforcing edge will be intended to be attached to a device around the periphery of a pressure balancing opening with which it is provided.

Furthermore, in these two embodiments described just above, the entire 1st face of the support layer of the 2nd element of the reinforcing edge may be attached by thermal welding around the periphery of a pressure balancing opening of a device and, where appropriate, the remaining part of the 1st face of the support layer of the 1st element of the reinforcing edge may be attached by thermal welding around the periphery of the pressure balancing opening of the device.

In these embodiments of the invention, the thermal welds may be carried out by methods such as ultrasonic or laser welding.

The method for manufacturing the pressure balancing membrane according to the invention is perfectly within the reach of a person skilled in the art.

The invention also relates to a device including a surface which comprises a pressure balancing opening, said opening being covered with a pressure balancing membrane according to the invention as described above.

The device can be selected from sealed enclosures of earthmoving equipment, road construction equipment, cranes, forklifts, tractors, electric charging stations, wind turbines, solar panels, shipping containers, boats, car headlights or spotlights for external use.

In the embodiments of the invention in which the membrane is double-layer and comprises a 1st layer of microporous film of polymeric material as described above and a 2nd layer of textile material as described above which is attached to said 1st layer of microporous film of polymeric material, preferably, and contrary to what is customary and therefore known from the prior art, the 1st layer of microporous film of polymeric material is preferably opposite the confined space of the device (in other words the 2nd layer of textile material is in contact with the external environment). This has the advantage of protecting the 1st layer of microporous film of polymeric material from external aggressions (for example gravel, insects) which are likely to damage it and/or tear it off.

The invention also relates to a method for protecting a pressure balancing opening emerging into a confined space of a device according to the invention as described above, which is characterized in that a pressure balancing membrane according to the invention as described above is attached around the entire periphery of said opening.

The invention will be better understood with the aid of the detailed description which is set out below with reference to the appended drawing representing, by way of non-limiting example, an embodiment of a balancing membrane according to the invention.

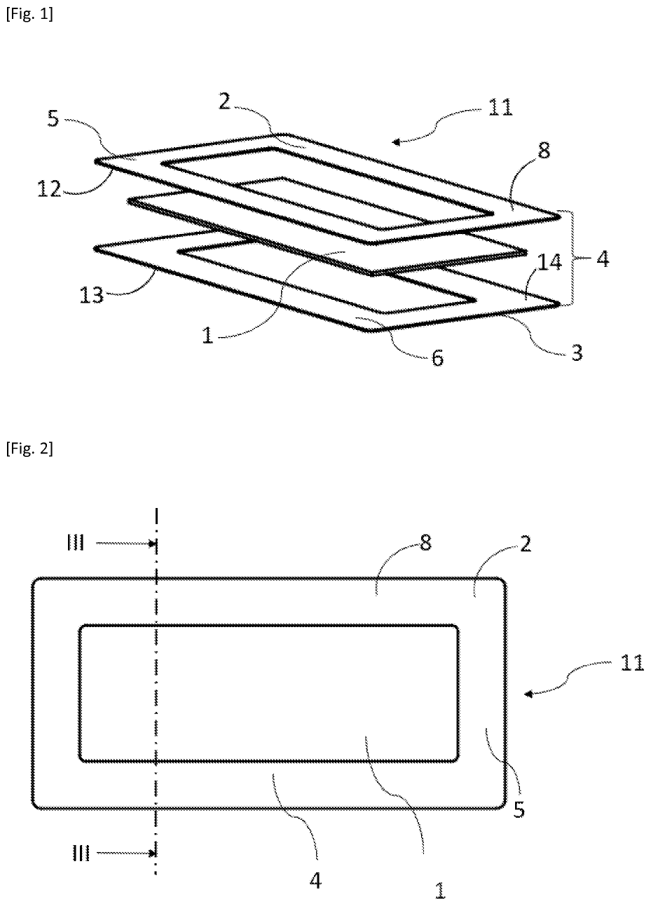

FIG. 1 is a perspective and exploded view of a pressure balancing membrane according to the invention.

FIG. 2 is a top view of said pressure balancing membrane according to the invention.

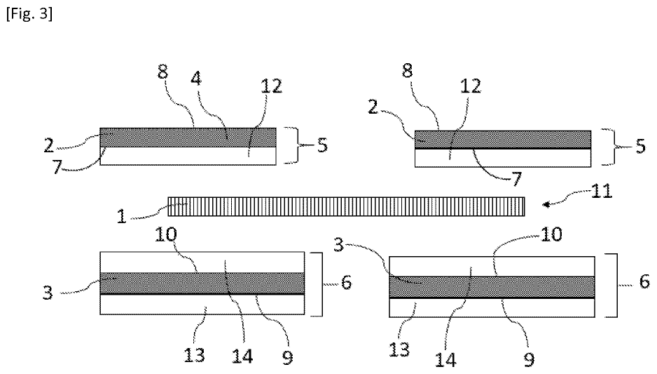

FIG. 3 is a sectional view along the axis III-III of FIG. 2 of said pressure balancing membrane according to the invention.

FIGS. 1 to 3 show a pressure balancing membrane 11 according to the invention which comprises:
a membrane 1 marketed under the trade name “QBV657D” by the company PARKER. This is a double-layer membrane comprising a layer of PTFE polymeric material film with a thickness of 15 μm onto which a layer of polyamide textile material with a thickness of 100 μm has been glued;
a reinforcing edge 4.

The membrane 1 has a rectangular shape with a length of 35 mm and a width of 15.5 mm.

The reinforcing edge 4 comprises a 1st element 5 and a 2nd element 6 which are configured to sandwich said membrane 1 around its entire periphery.

The 2nd element 6 of the reinforcing edge 4 is intended to be attached to a device (not represented in the figures) so that the pressure balancing membrane 11 covers a pressure balancing opening (not represented in the figures). The 1st element 5 of the reinforcing edge 4 is intended to be in contact with the environment external to said device.

The 1st and 2nd elements (5, 6) of the reinforcing edge 4 each have the shape of a frame whose opening has a shape similar to the periphery of the membrane 1.

More specifically, the 1st element 5 has the shape of a rectangular frame with the following dimensions:
the external dimensions of the frame are a length of 40 mm and a width of 19.5 mm;
the internal dimensions of the frame are a length of 32 mm and a width of 11.5 mm.

The 2nd element 6 has the shape of a rectangular frame with the following dimensions:
the external dimensions of the frame are a length of 40 mm and a width of 19.5 mm;
the internal dimensions of the frame are a length of 30 mm and a width of 9.5 mm.

In view of these dimensions, there is a coverage of:
2 mm in the width direction and 1.5 mm in the length direction between the 1st element 5 and the membrane 1;
3 mm in the width direction and 2.5 mm in the length direction between the 2nd element 6 and the membrane 1.

The 1st element 5 comprises a support layer 2 of PET with a thickness of 50 μm.

The support layer 2 of the 1st element 5 has:
a 1st face 7 which is covered with a 1^{st} layer of acrylic adhesive 12 with a thickness of 90 μm;
a 2nd face 8.

The 2nd element 6 comprises a support layer 3 of PET with a thickness of 50 μm.

The support layer 3 of the 2nd element 6 has:
a 1st face 9 which is covered with a 2^{nd} layer of acrylic adhesive 13 with a thickness of 60 μm;
a 2nd face 10 which is covered with a 3rd layer of acrylic adhesive 14 with a thickness of 60 μm.

More precisely, the 2nd element 6 is made of a double-sided adhesive material marketed under the trade name “GERGOTAPE 296X” by the company GERGONNE SAS.

The pressure balancing membrane 11 shown in FIGS. 1 to 3 corresponds to the membrane IQ1 used in the experiments described below.

### Experimental Part

Experiments were carried out on pressure balancing membranes according to the invention and comparative ones in order to demonstrate the advantages and benefits provided by the pressure balancing membranes according to the invention.

The 7 pressure balancing membranes (IQ1 to IQ7) according to the invention had the following characteristics.

The 1st membrane IQ1 according to the invention corresponded to the membrane shown in FIGS. 1 to 3 and which was described above.

The 2nd pressure balancing membrane IQ2 according to the invention differed from the membrane IQ1 only in that the membrane was a membrane marketed under the trade name “M100WL” by the company BERGHOF. It was a double-layer membrane with a total thickness of 140 μm which comprised a layer of PTFE onto which a layer of non-woven textile material made of PET was glued.

The 3rd pressure balancing membrane IQ3 according to the invention differed from the membrane IQ1 only in that the membrane was a membrane marketed under the trade name “EN0711066” by the company DONALDSON. It was a double-layer membrane with a total thickness of 170 μm which comprised a layer of PTFE onto which a layer of non-woven textile material made of PET was glued.

The 4th pressure balancing membrane IQ4 according to the invention differed from the membrane IQ1 only in that the membrane was a membrane marketed under the trade name “EN0701435” by the company DONALDSON. It was a double-layer membrane which comprised a PTFE layer with a thickness of 50 μm onto which a layer of polyamide non-woven textile material with a thickness of 200 μm was glued.

Thus, the pressure balancing membranes IQ1 to IQ4 all had double-layer membranes and had the same dimensions with regard to the membrane and the reinforcing edge.

The 5th pressure balancing membrane IQ5 according to the invention differed from the membrane IQ1 in that:
the membrane was a single-layer membrane marketed under the trade name “MV72040” by the company MICROVENT. It was a single-layer PTFE membrane with a thickness of 200 μm;
the 2nd element of the reinforcing edge was a double-sided adhesive material marketed under the trade name “TESA 4965” by the company TESA.

More specifically, said 2nd element comprised a PET support layer with a thickness of 12 μm and had:
a 1st face which was covered with a layer of acrylic adhesive with a thickness of 97 μm;
a 2nd face which was covered with a layer of acrylic adhesive with a thickness of 97 μm.

The dimensions of the 5th pressure balancing membrane IQ5 according to the invention were as follows:
the membrane had a rectangular shape with a length of 40 mm and a width of 19.5 mm,
the 1st element of the reinforcing edge had the shape of a rectangular frame whose external dimensions of the frame were a length of 48 mm and a width of 27.5 mm and the internal dimensions of the frame were a length of 32 mm and a width of 11.5 mm;
the 2nd element of the reinforcing edge had the shape of a rectangular frame whose external dimensions of the frame were a length of 40 mm and a width of 19.5 mm and the internal dimensions of the frame were a length of 30 mm and a width of 9.5 mm.

In view of these dimensions, there was a coverage of:
4 mm in the width direction and 4 mm in the length direction between the 1st element of the reinforcing edge and the membrane;
5 mm in the width direction and 5 mm in the length direction between the 2nd element of the reinforcing edge and the membrane.

The 6th pressure balancing membrane IQ6 according to the invention differed from the membrane IQ5 in that:
the membrane was a single-layer PTFE membrane with a thickness of 150 μm;
the 2nd element of the reinforcing edge was a double-sided adhesive material,
the assembly consisting of this membrane and this 2nd element was marketed under the trade name “AVS 9” by the company GORE.

More precisely, the 2nd element had a total thickness of 140 μm and comprised a support layer which had:
a 1st face which was covered with a layer of silicone adhesive;
a 2nd face which was covered with a layer of silicone adhesive.

The 7th pressure balancing membrane IQ7 according to the invention differed from the membrane IQ5 in that:
the membrane was a membrane marketed under the trade name “M40W” by the company BERGHOF. It was a single-layer PTFE membrane with a thickness of 300 μm;
the 2nd element of the reinforcing edge was made of the same double-sided adhesive material as that of the membranes IQ1 to IQ4 (namely the double-sided adhesive material marketed under the trade name “GERGOTAPE 296X” by the company GERGONNE SAS).

Thus, the pressure balancing membranes IQ5 to IQ7 all had single-layer membranes and had the same dimensions with regard to the membrane and the reinforcing edge.

The 11 comparative pressure balancing membranes (C1 to C11) had the following characteristics.

The 1st comparative pressure balancing membrane C1 differed from the 1st pressure balancing membrane IQ1 according to the invention in that it did not have a reinforcing edge. It only comprised the same membrane as that of the pressure balancing membrane IQ1 but with different dimensions (namely a length of 40 mm and a width of 19.5 mm) and a means for attaching to a device. This attachment means was identical to the 2nd element of the reinforcing edge of the pressure balancing membrane according IQ1 to the invention. It therefore had the shape of a rectangular frame whose external dimensions corresponded to the dimensions of the membrane and was attached around the entire periphery of said membrane.

The 2nd comparative pressure balancing membrane C2 differed from the 2nd pressure balancing membrane IQ2 according to the invention in that it did not have a reinforcing edge. It only comprised the same membrane as that of the pressure balancing membrane IQ2 but with different dimensions (namely a length of 40 mm and a width of 19.5 mm) and a means for attaching to a device. This attachment means was identical to the 2nd element of the reinforcing edge of the pressure balancing membrane IQ2 according to the invention. It therefore had the shape of a rectangular frame whose external dimensions corresponded to the dimensions of the membrane and was attached around the entire periphery of said membrane.

The 3rd comparative pressure balancing membrane C3 differed from the 3rd pressure balancing membrane according IQ3 to the invention in that it did not have a reinforcing edge. It only comprised the same membrane as that of the pressure balancing membrane IQ3 but with different dimensions (namely a length of 40 mm and a width of 19.5 mm) and a means for attaching to a device. This attachment means was identical to the 2nd element of the reinforcing edge of the pressure balancing membrane IQ3 according to the invention. It therefore had the shape of a rectangular frame whose external dimensions corresponded to the dimensions of the membrane and was attached around the entire periphery of said membrane.

The 4th comparative pressure balancing membrane C4 differed from the 4th pressure balancing membrane IQ4 according to the invention in that it did not have a reinforcing edge but only comprised the same membrane as that of the pressure balancing membrane IQ4 but with different dimensions (namely a length of 40 mm and a width of 19.5 mm) and a means for attaching to a device. This attachment means was identical to the 2nd element of the reinforcing edge of the pressure balancing membrane IQ4 according to the invention. It therefore had the shape of a rectangular frame whose external dimensions corresponded to the dimensions of the membrane and was attached around the entire periphery of said membrane.

The 5th comparative pressure balancing membrane C5 differed from the 5th pressure balancing membrane IQ5 according to the invention in that it did not have a reinforcing edge but only comprised the same membrane as that of the pressure balancing membrane IQ5 and a means for attaching to a device. This attachment means was identical to the 2nd element of the reinforcing edge of the pressure balancing membrane according IQ5 to the invention. It therefore had the shape of a rectangular frame whose external dimensions corresponded to the dimensions of the membrane and was attached around the entire periphery of said membrane.

The 6th comparative pressure balancing membrane C6 differed from the 6th pressure balancing membrane IQ6 according to the invention in that it did not have a reinforcing edge but only comprised the same membrane as that of the pressure balancing membrane IQ6 and a means for attaching to a device. This attachment means was identical to the 2nd element of the reinforcing edge of the pressure balancing membrane IQ6 according to the invention. It therefore had the shape of a rectangular frame whose external dimensions corresponded to the dimensions of the membrane and was attached around the entire periphery of said membrane.

The 7th comparative pressure balancing membrane C7 differed from the 7th pressure balancing membrane IQ7 according to the invention in that it did not have a reinforcing edge. It only comprised the same membrane as that of the pressure balancing membrane IQ7 and a means for attaching to a device. This attachment means was identical to the 2nd element of the reinforcing edge of the pressure balancing membrane IQ7 according to the invention. It therefore had the shape of a rectangular frame whose external dimensions corresponded to the dimensions of the membrane and was attached around the entire periphery of said membrane.

The 8th comparative pressure balancing membrane C8 differed from the 1st pressure balancing membrane IQ1 according to the invention in that:
the dimensions of the membrane were different (namely a length of 40 mm and a width of 19.5 mm);
the internal dimensions of the frame of the 2nd element were different (namely a length of 32 mm and a width of 11.5 mm).

The 9th comparative pressure balancing membrane C9 differed from the 2nd pressure balancing membrane IQ2 according to the invention in that:
the dimensions of the membrane were different (namely a length of 40 mm and a width of 19.5 mm);
the internal dimensions of the frame of the 2nd element were different (namely a length of 32 mm and a width of 11.5 mm).

The 10th comparative pressure balancing membrane C10 differed from the 3rd pressure balancing membrane IQ3 according to the invention in that:
the dimensions of the membrane were different (namely a length of 40 mm and a width of 19.5 mm);
the internal dimensions of the frame of the 2nd element were different (namely a length of 32 mm and a width of 11.5 mm).

The 11th comparative pressure balancing membrane C11 differed from the 5th pressure balancing membrane IQ5 according to the invention in that the 1st element of the reinforcing edge had the shape of a rectangular frame whose external dimensions of the frame were a length of 40 mm and a width of 19.5 mm and the internal dimensions of the frame were a length of 30 mm and a width of 9.5 mm.

Thus, the balancing membranes IQ1 to IQ4 according to the invention all included a membrane whose surface was 542.5 mm² while the comparative balancing membranes C1 to C4 all included a membrane whose surface was 780 mm². These balancing membranes IQ1 to IQ4 according to the invention had the advantage of including less PTFE than the corresponding comparative balancing membranes C1 to C4.

The comparative pressure balancing membranes C8 to C11 were pressure balancing membranes in which the 1st element and the 2nd element sandwiched the membrane flush around its entire periphery. Thus, pressure balancing membranes C8 to C11 had a configuration similar to that of the ventilation device described in the U.S. Pat. No. 9,875,733 B2 cited above.

Test No. 1 Carried Out with the Double-Layer Membranes IQ1 to IQ4, C1 to C4 and C8 to C10

The pressure balancing membranes IQ1 to IQ4, C1 to C4 and C8 to C10 were stressed under a water jet from a KARCHER® high-pressure cleaner to evaluate the gain in delamination resistance of the membranes according to the invention compared to the comparative membranes.

The pressurized water jet simulated drastic conditions to which pressure balancing membranes can be subjected, namely for example severe weather.

24 hours before carrying out the test, the tested pressure balancing membranes were applied to a solid raw aluminum plate with a length of 400 mm. The plate was positioned so as to form an angle of 150° with the water jet of the high-pressure cleaner set to a pressure of 210 bars and setting the distance between the nozzle of said cleaner and the plate at 50 cm. The water jet thus struck the tested membranes.

The tests were carried out for a maximum duration of 2 minutes. However, Test No. 1 was stopped as soon as the entire tested pressure balancing membrane was destroyed. The water jet was moved from left to right throughout the test in order to stress the tested membranes. The nozzle movement speed was 5 back and forth movements per minute.

Test No. 2 Carried Out with the Single-Layer Membranes IQ5 to IQ7. C5 to C7 and C11

The procedure for the 2nd test was identical to that of the 1st test except that the criticality of the test was increased.

In fact, the aluminum plate was positioned so as to form an angle of 150° with the water jet of the high-pressure cleaner set at a pressure of 210 bars and by setting the distance between the nozzle of said cleaner and the plate at 35 cm (and no longer 50 cm). The water jet thus struck the tested membranes.

The tests were carried out for a maximum duration of 2 minutes. However, Test no. 2 was stopped as soon as the entire tested pressure balancing membrane was destroyed. The water jet was moved from left to right throughout the test in order to stress the tested membranes. The nozzle movement speed was 5 back and forth movements per minute.

Table 1 below details the results obtained with all the tested pressure balancing membranes. More specifically, for each tested membrane, the resistance time to pressurized water and its condition after stopping the test are indicated.

For the pressure balancing membranes comprising a double-layer membrane, the 2nd column of Table 1 indicates:
“Polymer” when the layer of microporous film of polymeric material (namely PTFE) of the membrane was exposed to the high-pressure water jet;
“Textile” when the layer of textile material (namely polyamide or PET) of the membrane was exposed to the high-pressure water jet.

Thus, for the membranes IQ1, IQ2, C1 and C2, both possible configurations were tested.

In the last column of Table 1, the following terms are understood:
“cohesive failure of the adhesive on [ . . . ] % of the surface”: at the end of the test, the tested pressure balancing membrane was detached from the aluminum plate on [ . . . ] % of the surface and part of the adhesive was found on the aluminum plate;
“adhesive failure between the membrane and the adhesive on [ . . . ] % of the surface”: at the end of the test, the tested pressure balancing membrane was detached from the aluminum plate on [ . . . ] % of the surface and all of the adhesive remained on the 2nd element of the reinforcing edge.

TABLE 1
detailing the results obtained with all pressure balancing
membranes tested on their resistance time and the condition
of the membrane after stopping the test

| | | Duration of | |
|---|---|---|---|
| Tested | External | resistance | Condition of the membrane after |
| membrane | face | (s) | stopping the test |
| C1 | Polymer | 10 | Tearing of the polymer layer over |
| | | | 100% of the surface |
| IQ1 | Polymer | 60 | Tearing of the polymer layer over |
| | | | 40% of the surface |
| C1 | Textile | 10 | Tearing of the textile layer over |
| | | | 100% of the surface |
| IQ1 | Textile | 120 | Intact membrane |
| C8 | Textile | 15 | Tearing of the textile layer over |
| | | | 100% of the surface |
| C2 | Polymer | 10 | Tearing of the polymer layer over |
| | | | 100% of the surface |
| IQ2 | Polymer | 120 | Intact membrane |
| C2 | Textile | 10 | Tearing of the textile layer over |
| | | | 100% of the surface |
| IQ2 | Textile | 120 | Intact membrane |
| C9 | Polymer | 10 | Tearing of the polymer layer over |
| | | | 100% of the surface |
| C3 | Textile | 10 | Tearing of the textile layer over |
| | | | 100% of the surface |
| IQ3 | Textile | 120 | Intact membrane |
| C10 | Textile | 15 | Tearing of the textile layer over |
| | | | 100% of the surface |
| C4 | Textile | 10 | Tearing of the textile layer over |
| | | | 100% of the surface |
| IQ4 | Textile | 120 | Intact membrane |
| C5 | | 80 | Adhesive failure between the |
| | | | membrane and the adhesive over |
| | | | 100% of the surface |
| IQ5 | | 120 | Intact membrane |
| C11 | | 80 | Adhesive failure between the |
| | | | membrane and the adhesive over |
| | | | 100% of the surface |
| C6 | | 80 | Cohesive failure of the adhesive over |
| | | | 100% of the surface |
| IQ6 | | 120 | Cohesive failure of the adhesive over |
| | | | 50% of the surface |
| C7 | | 90 | Adhesive failure between the |
| | | | membrane and the adhesive over |
| | | | 100% of the surface |
| IQ7 | | 120 | Adhesive failure between the |
| | | | membrane and the adhesive over 75% |
| | | | of the surface |

In view of the results detailed in Table 1 above, the following remarkable points are noted:
Unlike pressure balancing membranes C1 to C4, the pressure balancing membranes IQ1 to IQ4 according to the invention all remain intact after 2 minutes of Test no. 1. They are not damaged when subjected to the pressurized water jet.
With regard to pressure balancing membrane IQ1, the latter remains intact in the configuration in which the textile material is exposed to the pressurized water jet. Indeed, in the configuration in which the PTFE film is exposed to the pressurized water jet, this PTFE layer is torn off over 40% of the surface of the membrane. This experiment demonstrates that it may be more advantageous for the balancing membranes according to the invention to expose the layer of textile material to the external environment.
Regarding the pressure balancing membrane IQ2, the latter remains intact regardless of the configuration, namely regardless of whether the textile material (PET) or the microporous film of polymeric material (PTFE) of the membrane is exposed to the pressurized water jet.
Test No. 2 was more drastic (reduced nozzle-aluminum plate distance). However, the pressure balancing membranes IQ5 to IQ7 according to the invention all resisted the pressurized water jet better than the comparative membranes C5 to C7. The membrane IQ5 remained intact at the end of the test.
Comparing the results of the membranes IQ6 and C6, the membrane IQ6 has a longer protection time (120 s versus 80 s) and is less damaged at the end of Test No. 2 (the cohesive failure of the adhesive occurred on 50% of the surface versus 100% of the surface for the membrane C6).
Comparative pressure balancing membranes C8 to C10 all deteriorated when subjected to the pressurized water jet.
Comparative pressure balancing membrane C11 did not withstand the pressurized water jet.

These experimental results demonstrate the better robustness and reliability of the pressure balancing membranes according to the invention in comparison with comparative pressure balancing membranes which are devoid of a reinforcing edge or in which the 1st element and the 2nd element of the reinforcing edge are located flush with the membrane as is the case in the ventilation device described in the U.S. Pat. No. 9,875,733 B2.

Furthermore, as recalled above, some of the pressure balancing membranes according to the invention (namely IQ1 to IQ4) had the advantage of including less PTFE than the corresponding comparative pressure balancing membranes (namely C1 to C4). They therefore had a reduced environmental impact and were more economical.

1. A pressure balancing membrane including a membrane and a reinforcing edge, a part or the whole of the periphery of the membrane is sandwiched with the reinforcing edge which includes a 1st element and a 2nd element,
the 1st element and the 2nd element each comprise a support layer,
the support layer of the 1st element has a 1st face and a 2nd face,
the support layer of the 2nd element has a 1st face and a 2nd face, wherein:
a part of the 2nd face of the support layer of the 2nd element is attached to a part of the 1st face of the support layer of the 1st element, the remaining part of the 2nd face of the support layer of the 2nd element is attached to a part of the membrane, as well as the remaining part of the 1st face of the support layer of the 1st element is attached to a part of the membrane
or
the entire 2nd face of the support layer of the 2nd element is attached to the membrane and a part of the 1st face of the support layer of the 1st element is attached to the membrane.

2. The pressure balancing membrane according to claim 1, wherein the membrane is a single-layer microporous film of polymeric material which is selected from polytetrafluoroethylene (hereinafter abbreviated as “PTFE”), polychlorotrifluoroethylene (hereinafter abbreviated as “PCTFE”), polyvinyl fluoride (hereinafter abbreviated as “PVF”), polysiloxane, polycarbonate (hereinafter abbreviated as “PC”) and polyester.

3. The pressure balancing membrane according to claim 1, wherein the membrane is double-layer and comprises a 1st layer of microporous film of polymeric material selected from PTFE, PCTFE, PVF, polysiloxane, PC and polyester and a 2nd layer of textile material which is attached to the 1st layer of microporous film of polymeric material, the textile material being selected from textiles based on polyethylene terephthalate (hereinafter abbreviated as “PET”), polyamides, polypropylene, polyethylene, acrylic, PTFE, elastane, glass fibers, carbon or cellulose.

4. The pressure balancing membrane according to claim 1, wherein the 1st and 2nd elements of the reinforcing edge each have the shape of a frame whose opening has a shape similar to the periphery of the membrane.

5. The pressure balancing membrane according to claim 1, wherein the material of the support layer of the 1st element and of the 2nd element is selected from PET, poly(ethylene naphthalate) (abbreviated “PEN”), polyvinyl chloride (abbreviated “PVC”), polyamide, polypropylene and metal foil, the material of the support layer of the 1st element being the same as or different from the material of the support layer of the 2nd element.

6. The pressure balancing membrane according to claim 1, wherein:
the 1st face of the support layer of the 1st element is covered with an adhesive,
the 2nd face of the support layer of the 2nd element is covered with an adhesive.

7. The pressure balancing membrane according to claim 6, wherein the 1st face of the support layer of the 2nd element is covered with an adhesive.

8. The pressure balancing membrane according to claim 6, wherein the adhesive is selected from pressure-sensitive adhesives.

9. A device including a surface which comprises a pressure balancing opening, the opening being covered with a pressure balancing membrane according to claim 1.

10. The device according to claim 9, wherein it is selected from the sealed enclosures of earthmoving equipment, road construction equipment, cranes, forklifts, tractors, electric charging stations, wind turbines, solar panels, shipping containers, boats, car headlights or spotlights for external use.

11. A method for protecting a pressure balancing opening emerging into a confined space of a device that includes a surface which comprises a pressure balancing opening, the opening being covered with a pressure balancing membrane according to claim 1, wherein the pressure balancing membrane is attached around the entire periphery of the opening.
